(19) United States
(12) Patent Application Publication
(10) Pub. No.: US 2015/0017339 A1
(43) Pub. Date: Jan. 15, 2015

(54) Substrate Structure Grown By Plasma Deposition

(71) Applicant: Fujifilm Manufacturing Europe B.V., Tilburg (NL)

(72) Inventors: Hindrik Willem DE VRIES, Tilburg (NL); Mauritius Cornelius Maria VAN DE SANDEN, Tilburg (NL)

(21) Appl. No.: 14/299,238

(22) Filed: Jun. 9, 2014

Related U.S. Application Data
(62) Division of application No. 13/318,238, filed on Oct. 31, 2011, now abandoned.

(30) Foreign Application Priority Data
Jun. 11, 2009 (GB) 0910040.5

(51) Int. Cl. C23C 16/513

(52) U.S. Cl. CPC C23C 16/513
USPC 427/453; 427/446; 427/450; 427/452

(57) ABSTRACT

Substrate structure comprising a substrate (6) and a plasma grown layer (6a). The surface of the resulting substrate structure (7) is characterized by interrelated scaling components. The scaling components comprise a roughness exponent α, a growth exponent β and a dynamic exponent z, wherein the growth exponent β has a value of less than 0.2 and the dynamic exponent z has a value of more than 6. Also disclosed is a method to provide such a substrate structure.

### FIELD OF THE INVENTION

The present invention relates to a substrate structure comprising a substrate and a plasma grown layer, the surface of the resulting substrate structure being characterized by interrelated scaling components, the scaling components comprising a roughness exponent α, a growth exponent β and a dynamic exponent z. In a further aspect, the present invention relates to a method for producing a substrate structure comprising providing a substrate in a treatment space, providing a gas mixture in the treatment space, and applying a plasma in the treatment space to deposit a layer of material on a surface of the substrate, wherein the surface of the resulting substrate structure is characterized by interrelated scaling components, the scaling components comprising a roughness exponent α, a growth exponent β and a dynamic exponent z.

### PRIOR ART

Thin films on substrates which are grown using various processes may be characterized by certain characteristic parameters, such as surface roughness α. Further characteristic parameters are growth exponent β and dynamic exponent z. These three parameters are in general interrelated as z≈α/β.

The components thus formed (thin film on substrate) may be applied in various applications, such as semiconductor processing, optical coating, plasma etching, patterning, micromachining, polishing, tribology, etc.

The specific details of the growth of the thin film such as the nature of the substrate, the source material, the deposition pressure and temperature and numerous other factors have been found not to contribute to the values of the growth exponent β.

This concept is known as universality. According the universality theory there is a strict relation between growth β and roughness α exponents, depending on the surface relaxation mechanism. Those related values form so called universality classes.

### SUMMARY OF THE INVENTION

According to the present invention, a substrate structure according to the preamble defined above is provided, wherein the growth exponent β has a value of less than 0.2 and the dynamic exponent z has a value of more than 6. This characterization of the surface of a substrate structure with a thin film layer was yet unknown. The combination of a very low growth exponent β (β≦0.2) and a high dynamic exponent z (z≧6) result in a yet unknown universality class. These characteristic features of the substrate structure (substrate with thin layer) may be exploited in various applications.

In a further embodiment, the dynamic exponent z has a value of about 9, e.g. 10. This allows to have layers of various thickness, without influencing other characteristic features such as surface roughness. Furthermore, in an even further embodiment, the roughness exponent α has a value of about 0.9.

The growth exponent β has a value of equal to or less than 0.1 in an even further embodiment. The value of the growth exponent can even be as small as 0.01, or even 0. This provides a substrate structure with even better properties, where the roughness of its surface is not influenced by a thickness t of the deposited thin layer. This allows the purposeful design of structures over a wide range of thickness of the substrate.

The substrate is provided with protrusions on its surface having a first height h₁, and the layer is grown to a thickness t which is smaller than the first height h₁ in a further embodiment. This may provide for a substrate structure with an ‘open’ surface, as a small part of the vertical wall of the protrusion remains without the added layer.

In an alternative embodiment, the substrate is provided with protrusions on its surface having a first height h₁, and the layer is grown to a thickness t which is larger than the first height h₁. As a result of the substrate structure characteristics, this ensures that the layer seals off any possible protrusions on the substrate (such as impurities or particles) and provides a closed surface, which is particularly advantageous when manufacturing barriers.

In a further embodiment, the protrusions comprise a pattern. This would e.g. allow to manufacture membranes having a high selectivity.

In a further aspect, a method is provided as described in the preamble above, wherein the growth exponent β has a value of less than 0.2 and the dynamic exponent z has a value of more than 6. In further embodiment, the method is further arranged to provide a substrate structure for which the various scaling components α, β and z have values in ranges as discussed above relating to various embodiments of the substrate structure.

In a further embodiment of the present method, the substrate is provided with protrusions on its surface having a first height h₁. Using the present method of uni-directional deposition, this allows to grow layers on a substrate, wherein the form of the protrusions is accurately preserved.

The thickness of the layer is adapted to a maximum size of particles possibly present in the treatment space in a further embodiment, to allow formation of a complete thin layer without any openings.

In a further embodiment, the plasma is an atmospheric pressure glow discharge plasma which is generated using an AC power supply having a duty cycle of up to 100%. Such a power supply allows to provide a very uniform and stable plasma, resulting in very efficient layer depositions.

In a further embodiment, the plasma is an atmospheric pressure glow discharge plasma which is generated comprising an oxygen concentration from 6% to 21% in the treatment space.

In an even further aspect, the present invention relates to a substrate deposition apparatus comprising a treatment space formed between at least two electrodes, a power supply connected to the at least two electrodes, the power supply being arranged to generate an plasma in the treatment space, a gas supply for providing a gas mixture in the treatment space, wherein the surface deposition apparatus is arranged to implement the method according to any one of the method embodiments as described above.

### SHORT DESCRIPTION OF DRAWINGS

The present invention will be discussed in more detail below, using a number of exemplary embodiments, with reference to the attached drawings, in which

FIG. 1 shows a cross sectional view of an exemplary embodiment of a substrate structure according to the present invention;

FIG. 2 shows a schematic diagram of a substrate deposition apparatus according to an embodiment of the present invention;

FIG. 3 shows a graph representing a number of characterizing parameters of a substrate surface;

FIG. 4 shows a graph of measured rms roughness of a number of exemplary embodiments of substrate structures according to the present invention;

FIG. 5 shows a graph of the auto-correlation function of surface heights separated laterally by a vector r;

FIGS. 6a and 6b show cross sectional views of further exemplary embodiments of the substrate structure according to the present invention;

FIG. 7a shows a graph presenting the height-height correlation function for various embodiments of the substrate structure of the present invention, in which HMDSO has been used as precursor; and

FIG. 7b shows a graph presenting the height-height correlation function for various embodiments of the substrate structure of the present invention, in which TEOS has been used as precursor.

### DETAILED DESCRIPTION OF EXEMPLARY EMBODIMENTS

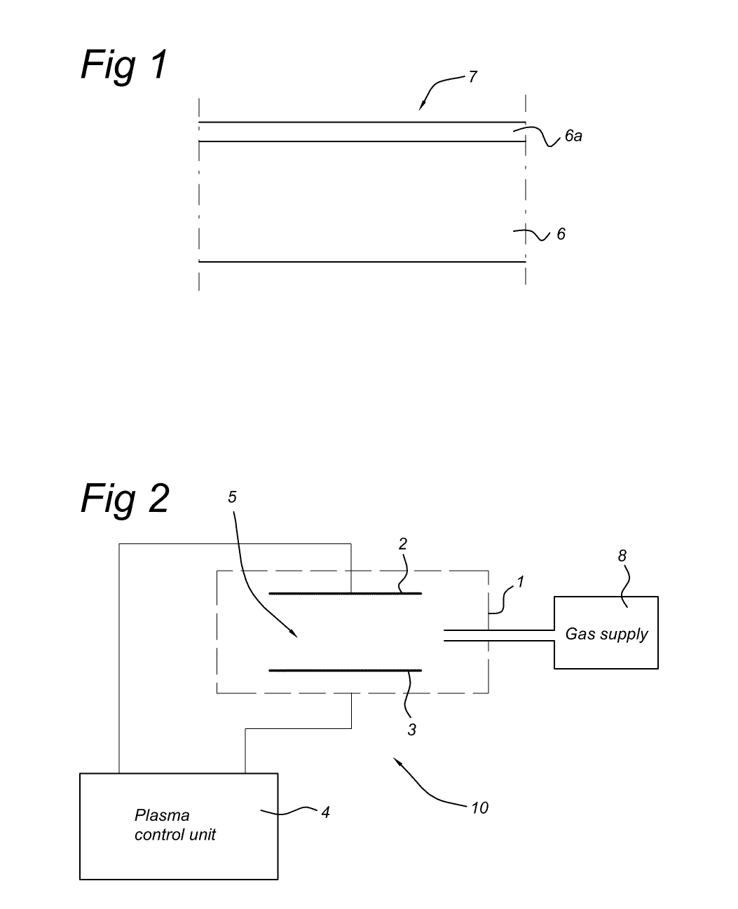

The present invention embodiments relate to layer deposition processes on a substrate film 6, using an atmospheric pressure glow discharge plasma in a treatment space of a substrate deposition apparatus 10 to deposit a thin film layer 6a on the substrate 6 to obtain a substrate structure 7, as shown in cross section in FIG. 1. Furthermore, the substrate structure 7 obtained using this process (substrate provided with a layer or thin film) is characterized by specific surface properties of the substrate structure 7. These specific surface characteristics make the substrate structure 7 very suitable for production of several semi-finished products. E.g. polymer films may be used as substrate 6, onto which a layer 6a of SiO₂ may be deposited to obtain substrate structures 7 in the form of foils or films with specific characteristics such as improved water vapor transmission ratio (WVTR) or oxygen transmission ratio (OTR). These semi-finished products may then be used for manufacturing LCD-screens, photo-voltaic cells, etc.

FIG. 2 shows a schematic view of a plasma treatment apparatus 10 in which the substrate structures 7 according to the present invention may be obtained. A treatment space 5, which may be a treatment space within an enclosure 1 or a treatment space 5 with an open structure, comprises two opposing electrodes 2, 3. A substrate 6, or two substrates 6 can be treated in the treatment space 5, e.g. in the form of flat sheets (stationary treatment, shown in FIG. 2) or in the form of moving webs.

In the treatment space 5, a mixture of gasses is introduced using gas supply device 8, including a reactive gas and a pre-cursor. It was observed that the oxygen as a reactive gas needs to be controlled in the range above 5% (e.g. 6%, 10%, 15%) up to 21% in the treatment space to make the inventive products.

The gas supply device 8 may be provided with storage, supply and mixing components as known to the skilled person. The purpose is to have the precursor decomposed in the treatment space 5 to a chemical compound or chemical element which is deposited on the substrate 6 as thin layer 6a.

In the plasma treatment apparatus 10, the electrodes 2, 3 are connected to a plasma control unit 4, which inter alia supplies electrical power to the electrodes 2, 3, i.e. functions as power supply. The plasma discharge in the treatment space 5 is controlled by special circuitry to sustain a very uniform plasma discharge at atmospheric pressure, even up to a 100% duty cycle. Both electrodes 2, 3 may have the same configuration being flat orientated (as shown in FIG. 2) or both being roll-electrodes. Also different configurations may be applied using roll electrode 2 and a flat or cylinder segment shaped electrode 3 opposing each other. A roll-electrode 2, 3 is e.g. implemented as a cylinder shaped electrode, mounted to allow rotation in operation e.g. using a mounting shaft or bearings. The roll-electrode 2, 3 may be freely rotating, or may be driven at a certain angular speed, e.g. using well known controller and drive units. Both electrodes 2, 3 can be provided with a dielectric barrier layer, or the substrate 6 can act as dielectric barrier layer.

The morphology of thin films has been investigated thoroughly and extensively, in search of ever better materials for production of various components and products. The book by M. Pellicone and Toh-Ming Lu ‘Evolution of Thin Film Morphology—Modeling and Simulations’, Springer Verlag, 2008, describes theories and models related to surface characteristics, e.g. surfaces grown as thin films 6a on substrates 6. More specifically the morphology evolution during thin film growth is discussed broadly.

It has now been found that when producing thin film layers 6a on substrates 6, using atmospheric pressure glow discharge plasma (as e.g. described in the patent application WO2009/104957 of applicant, herein incorporated by reference), surprisingly substrate structures 7 possibly may be provided having surface parameters which as of yet have not been observed in other deposition techniques. It is noted that the patent application WO2009/104957 discloses an example of providing thin film layers 6a on a substrate 6 using an APG plasma apparatus controlling the parameters g (gap distance) and d (total dielectric distance) to within specified ranges. No disclosure is made of characterizing parameters α, β and z of the substrates obtained as discussed in relation to the present invention embodiments described below. It is understood that using the techniques described in WO2009/104957, substrate structures 7 may be provided which fall within or outside the region of the parameters β and z as claimed in the present invention.

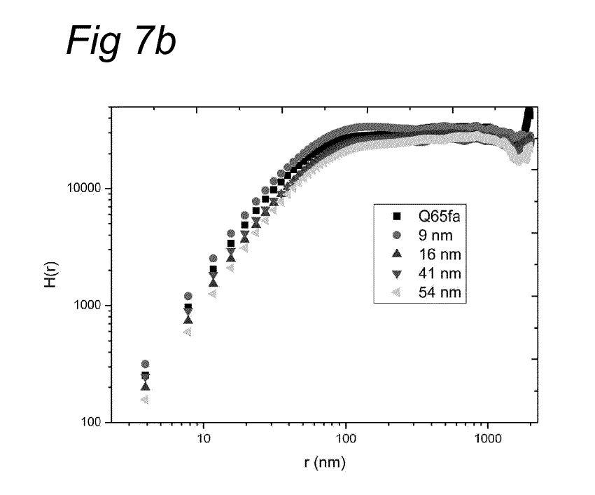

To investigate the growth mechanism of the substrate structures 7 obtained using an atmospheric pressure glow discharge deposition process, a large number of thin films 6a with varying thickness were deposited on a reference polymeric films 6, so-called APS-PEN or PET (Q65FA) under various oxygen concentration in the treatment space 5. The thickness was varied by changing the line speed of the moving webs 6. The PEN-polymer films 6 were deposited using HMDSO as precursor. Similar experiments were conducted using TEOS as a precursor and a PET (Q65FA) polymeric film 6. The polymer films 6 were deposited using HMDSO as precursor with 19, 24, 99, 142 and 310 nm thick SiO₂ layers 6a (see FIG. 7a), and similarly, using TEOS as a precursor, and a Q65FA polymeric film 6, on which thin films 6a were deposited in thicknesses of 9, 16, 41 and 54 nm SiO₂ (see FIG. 7b)

Subsequently, the bare polymer film 6 and the series of SiO₂ films 6a were characterized on surface roughness using an atomic force microscope (AFM). The surfaces were characterized on 2×2 micron scale to investigate roughness on the submicron level.

Based on the general theory of scaling of surfaces roughness as described in “Evolution of Thin Film Morphology Modeling and Simulations” by Matthew Pelliccione and Toh-Ming Lu published in Springer Series in Material science the surfaces were characterized. In addition, the open source software “Gwyddion” was used to perform the specific calculation of the surface statistics.

Experimentally, one can measure three scaling exponents α, β and z from different surface statistics from the thin films 6a and bare substrate 6, as will be described in detail below.

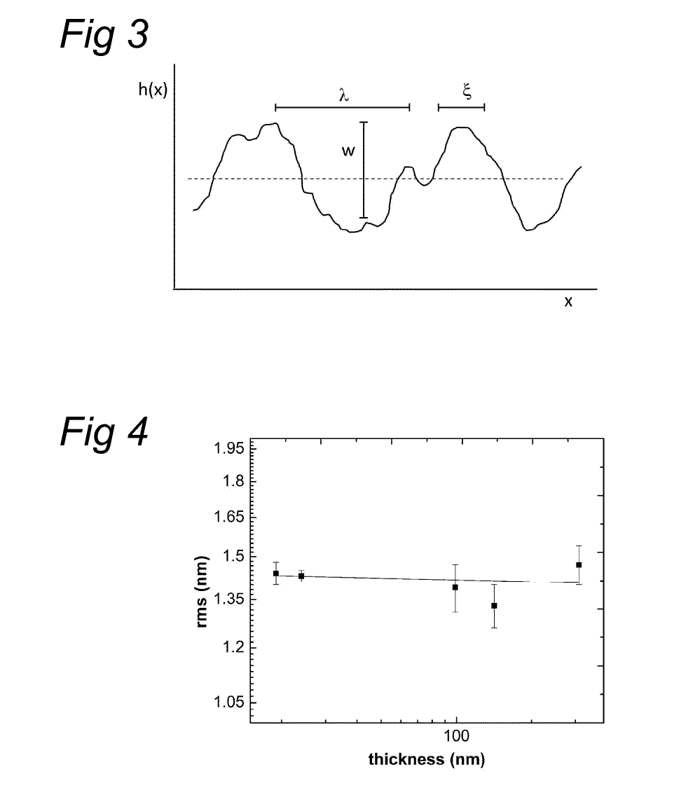

In FIG. 3, a schematic drawing of an exemplary surface profile is shown, with related parameters λ (wavelength of surface peaks), ξ (lateral correlation length of peaks) and w (interface width).

The mean height h(t) is defined by: h(t)≡<h(x,t)>, where x is the lateral dimension as shown in the surface profile of FIG. 3, and t is the thickness of the thin layer 6a. The interface width w is defined as the RMS roughness: w(t)≡\sqrt{<[h(x,t)]²>}. In general, the interface width is a function of the thin layer 6a thickness t, according to w(t)˜t^{α} in which β is the growth exponent.

Analyzing RMS roughness w(t) as a function of the film thickness t shows that there is no growth of the surface roughness as a function of film thickness t. By plotting RMS roughness w(t) and film thickness t as a log-log plot the slope of the fit will directly yield the growth exponent β. As can be seen in the plot shown in FIG. 4, for the exemplary substrate structure 7 (for the deposition on APS-PEN using HMDSO and an oxygen concentration of 21% in the treatment space 5), the growth exponent β is about zero (β=0). This means that the surface roughness does not increase when the thickness t of the thin layer 6a of the substrate structure 7 increases. This may be exploited in various applications, where thickness of the thin layer 6a of the substrate structure 7 may be varied to fulfill other requirements, while keeping the surface roughness almost the same. E.g. barrier substrates may be manufactured in the form of such a substrate structure 7 wherein the barrier function may impose requirements on minimum or maximum thickness. Alternatively, substrate structures 7 acting as membranes with a high selectivity may be provided, where also requirements may exist with regard to total thickness.

The correlations in lateral direction can be characterized by the Auto Correlation Function (ACF), see also chapter 2 ‘Surface Statistics’ in the book by Pelliccione et al. mentioned above. The ACF measures the correlation of surface heights separated laterally by a vector r.

R(Ξ,t)≡w⁻²<h(x,ε)h(x+r,ε)>

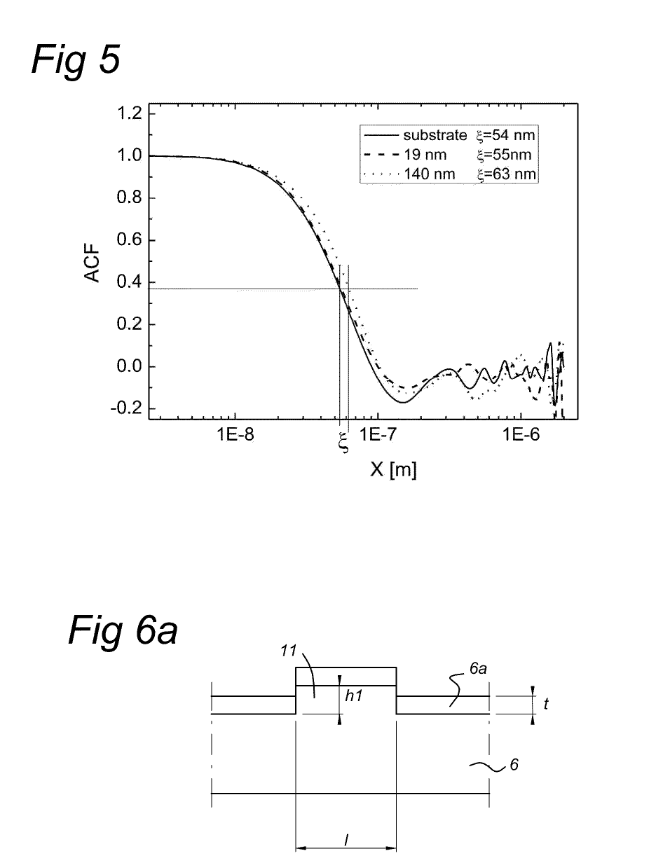

From the bare polymer surface 6 and the substrate structures 7 having thin layer films 6a of 19 and 140 nm SiO₂, the Auto Correlation Function (ACF) was determined. The result is shown in the plot of FIG. 5. The Lateral Correlation Function (LCF) (see also chapter 2 of the book by Pelliccione et al) is defined by the 1/e decrease of the ACF. Corresponding value of x at 1/e is the value Ξ (lateral correlation length of peaks):

R(Ξ,t)≡e⁻¹

Ξ(t)˜t^{1/e}
where z is the dynamic exponent. As can be seen in FIG. 5 the value for Ξ is hardly changing with the thickness t of the thin layer 6a which indicates that the value for z is large. Analysis of the complete set of films prepared using HMDSO as precursor (see FIG. 7a) indicates that values above 6 (i.e. 6.4 or even 9.4) can be derived, so a value of z of about 9 is achievable. Analysis of the complete set of films prepared using TEOS as precursor (see FIG. 7b) indicate that values of z above 8 can be derived.

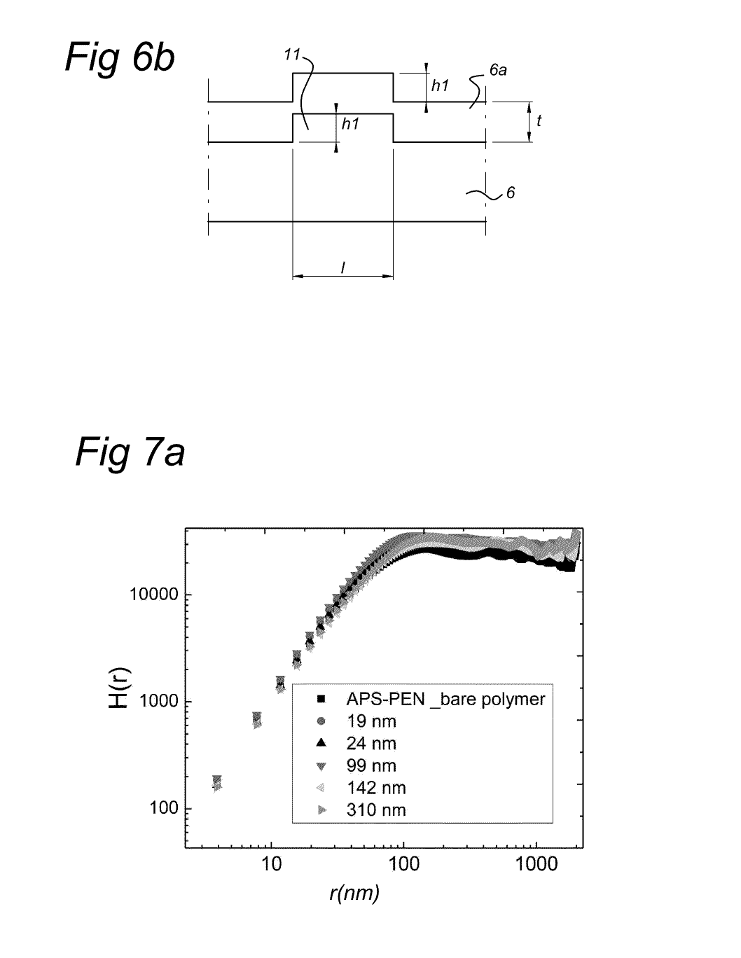

Substrate structures 7 with such a high value of the dynamic exponent z exhibit an important characteristic, which can be exploited for many applications. FIGS. 6a and 6b depict schematically in cross sectional view two examples of a substrate structure 7 with a thin film 6a deposited as described above. In both examples, the substrate 6 is provided with a peak 11 extending a height h₁ above the surface of the substrate 6. When such a peak 11 is present on a surface, the dynamic factor z is high (in the order of magnitude of 10, as shown above), and a thin layer 6a is grown on the surface of the substrate 6, the shape of the peak 11 is maintained almost independent on the thickness t of the layer 6a. When e.g. the surface of the substrate 6 is provided with a peak 11 in the form of a rectangular protrusion with a width 1 (as shown in the cross sectional view of FIG. 6a) and a thin layer 6a is deposited having a thickness t₁, the shape is maintained. When the height h1 of the protrusion 11 is larger than the thickness t₁ this causes openings in the layer 6a, which effect may e.g. be exploited to manufacture membranes with well-defined pore (opening) sizes, filters and the like.

Also when the height h₁ of the protrusion 11 is smaller than the deposited thickness t₁, a closed of surface of the thin layer 6a will result, however, with exactly the same protrusion shape in the surface of the thin layer 6a (as depicted in FIG. 6b). This effect may e.g. be advantageously exploited in applications where well defined patterns in a surface of a substrate structure 7 are needed, e.g. in foils for LCD screens.

The third scaling factor parameter α may be derived from measurements in the following manner. The Height-Height Correlation Function (HHCF) is defined as

H(r,t)=<[h(x+r,t)−h(x,t)]²>=2w²[1−R(r,t)]

In the case of a self-affine surface (see chapter 3 of the book by Pelliccione et al.) the height profile can be expressed as:

h(x)˜ε^{-α}h(εx)

In the case of small r the following equation can be derived

H(r,t)=<[h(x+r,t)−h(x,t)]²>˜<|(mr)^{α|2}>˜(mr)^{2x}

Then it follows that the height-height correlation function behaves as:

$$H ( r ) \text{?} \{ \begin{matrix}\text{?} , & r \text{?} \text{?} \\ \text{?} , & r \text{?} \text{?}\end{matrix} \\ \text{?} \text{indicates text missing or illegible when filed}$$

This behavior is also evident in the graphic plot for the various samples of substrate structures 7 as described above, as shown in FIG. 7a. From the height—height correlation function a value for α can be derived. In the case of the exemplary substrate structures 7 using HMDSO as precursor (FIG. 7a) as discussed above, it can be seen that the value of α is about 0.9, and does not depend very much on the thickness t of the thin film layer 6a. In the case of the exemplary substrate structures 7 using TEOS as precursor (FIG. 7b) as discussed above, it can be seen that the value of α is about 0.83, and again this value does not depend very much on the thickness t of the thin film layer 6a.

The well-known relationship between the scaling exponents under dynamic scaling is defined as z=α/β. Thus, to resume from the experimental substrate structures 7 it has been found that a substrate structure 7 has been provided for which the scaling parameters can be defined as: α˜0.9, β<0.1, z˜9 for HMDSO grown layers 6a, and α˜0.83, 62 <0.1, and z˜8 for TEOS grown layers 6a.

According the universality theory there is a strict relation between growth exponent β and roughness exponent α, depending on the surface relaxation mechanism.

Those related values form so called universality classes. The below table is a reproduction from the book by Pelliccione et al., and lists a number of different universality classes.

TABLE 3.1
Values for scaling exponents in various local growth models described by the continuum equation
∂h/∂t = Φ + η in 2 + 1 dimensions (d = 2), where η s random noise. In the bulk diffusion i model,
j_{z} is the flux of atoms along the z direction, which is related to the chemical potential μ as j_{z} ∝ −∂_{z}μ.

| Φ | Equation | α | β | z | Reference |
|---|---|---|---|---|---|
| v∇²h | Edwards-Wilkinson | ~0 | 0 | 2 | [38] |
| $v {∇}^{2} h + \frac{λ}{2} {\vert ∇ h \vert}^{2}$ | KPZ | 0.38 | 0.24 | 1.58 | [12, 61] |
| −κ∇⁴h | Surface diffusion | 1 | ¼ | 4 | [2, 25, 172] |
| Ω₀j_{z} | Bulk diffusion | 0.5 | 0.2 | 3.33 | [186] |
| v∇²h − κ∇⁴h | | 0 − 1 | 0 − 0.25 | 2 − 4 | [99] |
| $- κ {∇}^{4} h + \frac{λ}{2} {∇}^{2} {\vert ∇ h \vert}^{2}$ | Lai-Das Sarma | ⅔ | ⅕ | 10/3 | [74] |
| $- v {∇}^{2} h - κ {∇}^{4} h + \frac{λ}{2} {\vert ∇ h \vert}^{2}$ | KS (early time) | 0.75 − 0.80 | 0.22 − 0.25 | 3.0 − 4.0 | [33] |
| $- v {∇}^{2} h - κ {∇}^{4} h + \frac{λ}{2} {\vert ∇ h \vert}^{2}$ | KS (late time) | 0.25 − 0.28 | 0.16 − 0.21 | — | [33] |

The APG-CVD films 7 as described above, having as scaling parameters α˜0.9, β<0.1, z˜9 and α˜0.83, β<0.1, and z˜8, respectively, do not fall into any known universality class.

Also further embodiments fall into this yet unknown universality class, wherein the growth exponent β<0.2 and the dynamic exponent z>6. Further examples which expose advantageous characteristics relate to a substrate structure 7 where the growth exponent β<0.1, e.g. β<0.01. Other examples include but are not limited to substrate structures 7 wherein the dynamic exponent z has a value of 9 or even 10.

The uni-directional film deposition as described above, where the value of the dynamic exponent is very high (z≧6) can be utilized for example for a deposition process to obtain a substrate structure 7 in the form of a super barrier films in the case the substrate 6 is very smooth and does not contain any particles or features. Moreover the uni-directional film deposition can also be utilized to obtain substrate structures 7 which act as highly selective membranes. An even further application of the embodiments of the present substrate structure 7 may be found in the patterning of an inorganic layer by depositing a film on a substrate 6 containing photoresist patterns, e.g. the protrusions 11 as shown in FIG. 6a. For example, suppose that the height h1 in FIG. 6a comprises a photoresist pattern. Then, by depositing an inorganic film 6a uni-directionally on top of the patterned substrate 6 will lead to the growth of a film 6a with thickness t on the base substrate 6 and on the photoresist pattern 11 leaving the sides of the photoresist uncovered. Dissolving the photoresist will take away the parts of the film 6a on top of the photoresist pattern 11 and will result in a patterned inorganic, smooth and conformal film 6a on the substrate 6.

The substrates 6 used in this illustrative description has a thickness smaller than the gap distance g between the at least two opposing electrodes 2, 3 and may range from 20 μm to 800 μm, for example 50 μm or 100 μm or 200 μm and can be selected from: SiO₂ wafers, glasses ceramics, plastics and the like. By this method and apparatus layers of a chemical compound or chemical element can be deposited on substrates having a relatively low Tg, meaning that also common plastics, like polyethylene (PE), polypropylene (PP), Triacetylcellulose, PEN, PET, polycarbonate (PC) and the like can be provided with a deposition layer. Other substrates 6, 7 which can be chosen are for example UV stable polymer films such as ETFE or PTFE (from the group of fluorinated polymers) or silicone polymer foils. These polymers may even be reinforced by glass fibre to improve impact resistance.

The substrates provided with the deposition according to the present invention can be used in a wide range of applications like wafer manufacturing, they can be used as barrier for plastics or applications where a conductive layer on an isolator is required and the like. The present invention embodiments can be used advantageously for producing substrates having properties suitable for applications in e.g. OLED devices, or more general for substrates in the form of films or foils which are usable for protecting against deterioration by water and/or oxygen and having smooth properties e.g. barrier films in the field of flexible PV-cells.

In general, the gas mixture applied for providing the present embodiments of substrate structures 7 includes a reactive gas and a precursor. Although oxygen as a reactive gas has many advantages also other reactive gases might be used like for example hydrogen, carbon dioxide, ammonia, oxides of nitrogen, and the like.

The formation of a glow discharge plasma may be stimulated by controlling the displacement current (dynamic matching) using the plasma control unit 4 connected to the electrodes 2, 3, leading to a uniform activation of the surface of substrate in the treatment space 5. The plasma control unit 4 e.g. comprises a power supply and associated control circuitry as described in the pending international patent application PCT/NL2006/050209, and European patent applications EP-A-1381257, EP-A-1626613 of applicant, which are herein incorporated by reference.

Further the deposition may be stimulated by using heated substrate as described in WO2008/147184 of applicant, which is herein incorporated by reference. All illustrative examples have been prepared having a polymer 6 substrate temperature of 90° C.

In the present method precursors can be can be selected from (but are not limited to): W(CO)6, Ni(CO)4, Mo(CO)6, Co2(CO)8, Rh4(CO)12, Re2(CO)10, Cr(CO)6, or Ru3(CO)12, Bis(dimethylamino)dimethylsilane (BDMADMS), Tantalum Ethoxide (Ta(OC₂H₅)₅), Tetra Dimethyl amino Titanium (or TDMAT) SiH₄ CH₄, B₂H₆ or BCl₃, WF₆, TiCl₄, GeH4, Ge2H6Si2H6 (GeH3)3SiH, (GeH3)2SiH2, hexamethyldisiloxane (HMDSO), tetramethyldisiloxane (TMDSO), 1,1,3,3,5,5-hexamethyltrisiloxane, hexamethylcyclotetrasiloxane, octamethylcyclotetrasiloxane, decamethylcyclopentanesiloxane, tetraethoxysilane (TEOS), methyltrimethoxysilane, methyltriethoxysilane, dimethyldimethoxysilane, dimethyldiethoxysilane, trimethylethoxysilane, ethyltrimethoxysilane, ethyltriethoxysilane, n-propyltrimethoxysilane, n-propyltriethoxysilane, n-butyltrimethoxysilane, i-butyltrimethoxysilane, n-hexyltrimethoxysilane, phenyltrimethoxysilane, vinyltrimethoxysilane, vinyltriethoxysilane, aminomethyltrimethylsilane, dimethyldimethylaminosilane, dimethylaminotrimethylsilane, allylaminotrimethylsilane, diethylaminodimethylsilane, 1-trimethylsilylpyrrole, 1-trimethylsilylpyrrolidine, isopropylaminomethyltrimethylsilane, diethylaminotrimethylsilane, anilinotrimethylsilane, 2-piperidinoethyltrimethylsilane, 3-butylaminopropyltrimethylsilane, 3-piperidinopropyltrimethylsilane, bis(dimethylamino)methylsilane, 1-trimethylsilylimidazole, bis(ethylamino)dimethylsilane, bis(butylamino)dimethylsilane, 2-aminoethylaminomethyldimethylphenylsilane, 3-(4-methylpiperazinopropyl)trimethylsilane, dimethylphenylpiperazinomethylsilane, butyldimethyl-3-piperazinopropylsilane, dianilinodimethylsilane, bis(dimethylamino)diphenylsilane, 1,1,3,3-tetramethyldisilazane, 1,3-bis(chloromethyl)-1,1,3,3-tetramethyldisilazane, hexamethyldisilazane, 1,3-divinyl-1,1,3,3-tetramethyldisilazane, dibutyltin diacetate, aluminum isopropoxide, tris(2,4-pentadionato)aluminum, dibutyldiethoxytin, butyltin tris(2,4-pentanedionato), tetraethoxytin, methyltriethoxytin, diethyldiethoxytin, triisopropylethoxytin, ethylethoxytin, methylmethoxytin, isopropylisopropoxytin, tetrabutoxytin, diethoxytin, dimethoxytin, diisopropoxytin, dibutoxytin, dibutyryloxytin, diethyltin, tetrabutyltin, tin bis(2,4-pentanedionato), ethyltin acetoacetonato, ethoxytin (2,4-pentanedionato), dimethyltin (2,4-pentanedionato), diacetomethylacetatotin, diacetoxytin, dibutoxydiacetoxytin, diacetoxytin diacetoacetonato, tin hydride, tin dichloride, tin tetrachloride, triethoxytitanium, trimethoxytitanium, triisopropoxytitanium, tributoxytitanium, tetraethoxytitanium, tetraisopropoxytitanium, methyldimethoxytitanium, ethyltriethoxytitanium, methyltripropoxytitanium, triethyltitanium, triisopropyltitanium, tributyltitanium, tetraethyltitanium, tetraisopropyltitanium, tetrabutyltitanium, tetradimethylaminotitanium, dimethyltitanium di(2,4-pentanedionato), ethyltitanium tri(2,4-pentanedionato), titanium tris(2,4-pentanedionato), titanium tris(acetomethylacetato), triacetoxytitanium, dipropoxypropionyloxytitanium, dibutyryloxytitanium, monotitanium hydride, dititanium hydride, trichlorotitanium, tetrachlorotitanium, tetraethylsilane, tetramethylsilane, tetraisopropylsilane, tetrabutylsilane, tetraisopropoxysilane, diethylsilane di(2,4-pentanedionato), methyltriethoxysilane, ethyltriethoxysilane, silane tetrahydride, disilane hexahydride, tetrachlorosilane, methyltrichlorosilane, diethyldichlorosilane, isopropoxyaluminum, tris(2,4-pentanedionato)nickel, bis(2,4-pentanedionato)manganese, isopropoxyboron, tri-n-butoxyantimony, tri-n-butylantimony, di-n-butylbis(2,4-pentanedionato)tin, di-n-butyldiacetoxytin, di-t-butyldiacetoxytin, tetraisopropoxytin, zinc di(2,4-pentanedionate), and combinations thereof. Furthermore precursors can be used as for example described in EP-A-1351321 or EP-A-1371752. Generally the precursors are used in a concentration of 2-500 ppm e.g. around 50 ppm of the total gas composition.

### EXAMPLES

Several substrates 6 (APS-PEN/PET Q65FA) have been treated (17.8 cm width and thickness 100 μm) using an excitation energy of 150 kHz with a 100% duty cycle and heat controlled rotary electrodes 2,3 with a surface temperature of 90° C. Power supplied to the electrodes 2,3 is 500 W.

The gas composition in the treatment space comprised nitrogen and oxygen and HMDSO (1000 mg/hr). The concentration of oxygen was varied in the treatment space.

TABLE I

| | | O₂-concentration | | | |
|---|---|---|---|---|---|
| Substrate | precursor | (%) | α | β | z |
| APS-PEN | HMDSO | 0.5 | 0.71 | 0.40 | 1.75 |
| APS-PEN | HMDSO | 4 | 0.85 | 0.22 | 3.86 |
| APS-PEN | HMDSO | 6 | 0.89 | 0.14 | 6.36 |
| APS-PEN | HMDSO | 10 | 0.89 | 0.10 | 8.90 |
| APS-PEN | HMDSO | 21 | 0.89 | 0.095 | 9.37 |
| PET (Q65FA) | TEOS | 0.5 | 0.68 | 0.42 | 1.62 |
| PET (Q65FA) | TEOS | 10 | 0.81 | 0.097 | 8.35 |
| PET (Q65FA) | TEOS | 21 | 0.83 | 0.096 | 8.64 |

1. A method for producing a substrate structure comprising providing a substrate in a treatment space, providing a gas mixture in the treatment space, and applying a plasma in the treatment space to deposit a layer of material on a surface of the substrate, wherein the surface of the resulting substrate structure is characterized by interrelated scaling components, the scaling components comprising a roughness exponent α, a growth exponent β and a dynamic exponent z, wherein the growth exponent β has a value of less than 0.2 and the dynamic exponent z has a value of more than 6, wherein the gas mixture comprises oxygen gas in an amount between 5% and 21% and a pre-cursor.

2. The method according to claim 1, wherein the dynamic exponent z has a value of about 9.

3. The method according to claim 1, wherein the roughness exponent α has a value of about 0.9.

4. The method according to claim 1, wherein the growth exponent β has a value of less than 0.1.

5. The method according to claim 1, wherein the substrate is provided with protrusions on its surface having a first height h₁.

6. The method according to claim 1, wherein the thickness of the layer is adapted to a maximum size of particles possibly present in the treatment space.

7. The method according to claim 1, wherein the plasma is an atmospheric pressure glow discharge plasma which is generated using an AC power supply having a duty cycle of up to 100%.

8. The method according to claim 5 wherein the plasma is an atmospheric pressure glow discharge plasma which is generated using an AC power supply having a duty cycle of up to 100%.

9. The method according to claim 1 wherein the precursor is decomposed in the treatment space to a chemical compound or chemical element which is deposited on the substrate as a thin layer.

10. The method according to claim 1 wherein the precursor is selected from the group consisting of: W(CO)₆, Ni(CO)₄, Mo(CO)₆, Co₂(CO)₈, Rh₄(CO)₁₂, Re₂(CO)₁₀, Cr(CO)₆, or Ru₃(CO)₁₂, bis(dimethylamino)dimethylsilane, tantalum ethoxide (Ta(OC₂H₅)₅), tetra dimethyl amino titanium, SiH₄, CH₄, B₂H₆ or BCl₃, WF₆, TiCl₄, GeH₄, Ge₂H₆Si₂H₆, (GeH₃)₃SiH, (GeH₃)₂SiH₂, hexamethyldisiloxane, tetramethyldisiloxane, 1,1,3,3,5,5-hexamethyltrisiloxane, hexamethylcyclotetrasiloxane, octamethylcyclotetrasiloxane, decamethylcyclopentanesiloxane, tetraethoxysilane, methyltrimethoxysilane, methyltriethoxysilane, dimethyldimethoxysilane, dimethyldiethoxysilane, trimethylethoxysilane, ethyltrimethoxysilane, ethyltriethoxysilane, n-propyltrimethoxysilane, n-propyltriethoxysilane, n-butyltrimethoxysilane, i-butyltrimethoxysilane, n-hexyltrimethoxysilane, phenyltrimethoxysilane, vinyltrimethoxysilane, vinyltriethoxysilane, aminomethyltrimethylsilane, dimethyldimethylaminosilane, dimethylaminotrimethylsilane, allylaminotrimethylsilane, diethylaminodimethylsilane, 1-trimethylsilylpyrrole, 1-trimethylsilylpyrrolidine, isopropylaminomethyltrimethylsilane, diethylaminotrimethylsilane, anilinotrimethylsilane, 2-piperidinoethyltrimethylsilane, 3-butylaminopropyltrimethylsilane, 3-piperidinopropyltrimethylsilane, bis(dimethylamino)methylsilane, 1-trimethylsilylimidazole, bis(ethylamino)dimethylsilane, bis(butylamino)dimethylsilane, 2-aminoethylaminomethyldimethylphenylsilane, 3-(4-methylpiperazinopropyl)trimethylsilane, dimethylphenylpiperazinomethylsilane, butyldimethyl-3-piperazinopropylsilane, dianilinodimethylsilane, bis(dimethylamino)diphenylsilane, 1,1,3,3-tetramethyldisilazane, 1,3-bis(chloromethyl)-1,1,3,3-tetramethyldisilazane, hexamethyldisilazane, 1,3-divinyl-1,1,3,3-tetramethyldisilazane, dibutyltin diacetate, aluminum isopropoxide, tris(2,4-pentadionato)aluminum, dibutyldiethoxytin, butyltin tris(2,4-pentanedionato), tetraethoxytin, methyltriethoxytin, diethyldiethoxytin, triisopropylethoxytin, ethylethoxytin, methylmethoxytin, isopropylisopropoxytin, tetrabutoxytin, diethoxytin, dimethoxytin, diisopropoxytin, dibutoxytin, dibutyryloxytin, diethyltin, tetrabutyltin, tin bis(2,4-pentanedionato), ethyltin acetoacetonato, ethoxytin (2,4-pentanedionato), dimethyltin (2,4-pentanedionato), diacetomethylacetatotin, diacetoxytin, dibutoxydiacetoxytin, diacetoxytin diacetoacetonato, tin hydride, tin dichloride, tin tetrachloride, triethoxytitanium, trimethoxytitanium, triisopropoxytitanium, tributoxytitanium, tetraethoxytitanium, tetraisopropoxytitanium, methyldimethoxytitanium, ethyltriethoxytitanium, methyltripropoxytitanium, triethyltitanium, triisopropyltitanium, tributyltitanium, tetraethyltitanium, tetraisopropyltitanium, tetrabutyltitanium, tetradimethylaminotitanium, dimethyltitanium di(2,4-pentanedionato), ethyltitanium tri(2,4-pentanedionato), titanium tris(2,4-pentanedionato), titanium tris(acetomethylacetato), triacetoxytitanium, dipropoxypropionyloxytitanium, dibutyryloxytitanium, monotitanium hydride, dititanium hydride, trichlorotitanium, tetrachlorotitanium, tetraethylsilane, tetramethylsilane, tetraisopropylsilane, tetrabutylsilane, tetraisopropoxysilane, diethylsilane di(2,4-pentanedionato), methyltriethoxysilane, ethyltriethoxysilane, silane tetrahydride, disilane hexahydride, tetrachlorosilane, methyltrichlorosilane, diethyldichlorosilane, isopropoxyaluminum, tris(2,4-pentanedionato)nickel, bis(2,4-pentanedionato)manganese, isopropoxyboron, tri-n-butoxyantimony, tri-n-butylantimony, di-n-butylbis(2,4-pentanedionato)tin, di-n-butyldiacetoxytin, di-t-butyldiacetoxytin, tetraisopropoxytin, zinc di(2,4-pentanedionate), and combinations thereof.

11. The method according to claim 1 wherein the precursor is selected from the group consisting of: hexamethyldisiloxane, tetraethoxysilane, and combinations thereof.

12. The method according to claim 1 wherein the precursor is used in a concentration of 2-500 ppm of the total gas composition.

13. The method according to claim 10 wherein the precursor is used in a concentration of 2-500 ppm of the total gas composition.

14. The method according to claim 11 wherein the precursor is used in a concentration of 2-500 ppm of the total gas composition.

15. The method according to claim 1 wherein the precursor is used in a concentration of 2-500 ppm of the total gas composition and the precursor is decomposed in the treatment space to a chemical compound or chemical element which is deposited on the substrate as thin layer.

16. The method according to claim 15 wherein the precursor is selected from the group consisting of: W(CO)₆, Ni(CO)₄, Mo(CO)₆, Co₂(CO)₈, Rh₄(CO)₁₂, Re₂(CO)₁₀, Cr(CO)₆, or Ru₃(CO)₁₂, bis(dimethylamino)dimethylsilane, tantalum ethoxide (Ta(OC₂H₅)₅), tetra dimethyl amino titanium, SiH₄, CH₄, B₂H₆ or BCl₃, WF₆, TiCl₄, GeH₄, Ge₂H₆ Si₂H₆, (GeH₃)₃ SiH, (GeH₃)₂SiH₂, hexamethyldisiloxane, tetramethyldisiloxane, 1,1,3,3,5,5-hexamethyltrisiloxane, hexamethylcyclotetrasiloxane, octamethylcyclotetrasiloxane, decamethylcyclopentanesiloxane, tetraethoxysilane, methyltrimethoxysilane, methyltriethoxysilane, dimethyldimethoxysilane, dimethyldiethoxysilane, trimethylethoxysilane, ethyltrimethoxysilane, ethyltriethoxysilane, n-propyltrimethoxysilane, n-propyltriethoxysilane, n-butyltrimethoxysilane, i-butyltrimethoxysilane, n-hexyltrimethoxysilane, phenyltrimethoxysilane, vinyltrimethoxysilane, vinyltriethoxysilane, aminomethyltrimethylsilane, dimethyldimethylaminosilane, dimethylaminotrimethylsilane, allylaminotrimethylsilane, diethylaminodimethylsilane, 1-trimethylsilylpyrrole, 1-trimethylsilylpyrrolidine, isopropylaminomethyltrimethylsilane, diethylaminotrimethylsilane, anilinotrimethylsilane, 2-piperidinoethyltrimethylsilane, 3-butylaminopropyltrimethylsilane, 3-piperidinopropyltrimethylsilane, bis(dimethylamino)methylsilane, 1-trimethylsilylimidazole, bis(ethylamino)dimethylsilane, bis(butylamino)dimethylsilane, 2-aminoethylaminomethyldimethylphenylsilane, 3-(4-methylpiperazinopropyl)trimethylsilane, dimethylphenylpiperazinomethylsilane, butyldimethyl-3-piperazinopropylsilane, dianilinodimethylsilane, bis(dimethylamino)diphenylsilane, 1,1,3,-tetramethyldisilazane, 1,3-bis(chloromethyl)-1,1,3,3-tetramethyldisilazane, hexamethyldisilazane, 1,3-divinyl-1,1,3,3-tetramethyldisilazane, dibutyltin diacetate, aluminum isopropoxide, tris(2,4-pentadionato)aluminum, dibutyldiethoxytin, butyltin tris(2,4-pentanedionato), tetraethoxytin, methyltriethoxytin, diethyldiethoxytin, triisopropylethoxytin, ethylethoxytin, methylmethoxytin, isopropylisopropoxytin, tetrabutoxytin, diethoxytin, dimethoxytin, diisopropoxytin, dibutoxytin, dibutyryloxytin, diethyltin, tetrabutyltin, tin bis(2,4-pentanedionato), ethyltin acetoacetonato, ethoxytin (2,4-pentanedionato), dimethyltin (2,4-pentanedionato), diacetomethylacetatotin, diacetoxytin, dibutoxydiacetoxytin, diacetoxytin diacetoacetonato, tin hydride, tin dichloride, tin tetrachloride, triethoxytitanium, trimethoxytitanium, triisopropoxytitanium, tributoxytitanium, tetraethoxytitanium, tetraisopropoxytitanium, methyldimethoxytitanium, ethyltriethoxytitanium, methyltripropoxytitanium, triethyltitanium, triisopropyltitanium, tributyltitanium, tetraethyltitanium, tetraisopropyltitanium, tetrabutyltitanium, tetradimethylaminotitanium, dimethyltitanium di(2,4-pentanedionato), ethyltitanium tri(2,4-pentanedionato), titanium tris(2,4-pentanedionato), titanium tris(acetomethylacetato), triacetoxytitanium, dipropoxypropionyloxytitanium, dibutyryloxytitanium, monotitanium hydride, dititanium hydride, trichlorotitanium, tetrachlorotitanium, tetraethylsilane, tetramethylsilane, tetraisopropylsilane, tetrabutylsilane, tetraisopropoxysilane, diethylsilane di(2,4-pentanedionato), methyltriethoxysilane, ethyltriethoxysilane, silane tetrahydride, disilane hexahydride, tetrachlorosilane, methyltrichlorosilane, diethyldichlorosilane, isopropoxyaluminum, tris(2,4-pentanedionato)nickel, bis(2,4-pentanedionato)manganese, isopropoxyboron, tri-n-butoxyantimony, tri-n-butylantimony, di-n-butylbis(2,4-pentanedionato)tin, di-n-butyldiacetoxytin, di-t-butyldiacetoxytin, tetraisopropoxytin, zinc di(2,4-pentanedionate), and combinations thereof.

17. The method according to claim 15 wherein the precursor is selected from the group consisting of: hexamethyldisiloxane, tetraethoxysilane, and combinations thereof.
